(19) United States
(12) Patent Application Publication
(10) Pub. No.: US 2012/0119327 A1
(43) Pub. Date: May 17, 2012

(54) CAPACITOR AND SEMICONDUCTOR DEVICE INCLUDING A CAPACITOR

(76) Inventors: Oh-Seong Kwon, Hwaseong-si (KR); Kyu-Ho Cho, Hwaseong-si (KR); Wan-Don Kim, Yongin-si (KR); Beom-Seok Kim, Suwon-si (KR); Yong-Suk Tak, Seoul (KR)

(21) Appl. No.: 13/238,032

(22) Filed: Sep. 21, 2011

(30) Foreign Application Priority Data
Nov. 15, 2010 (KR) 10-2010-0113110

(51) Int. Cl. H01L 29/92

(52) U.S. Cl. 257/532; 257/E29.342

(57) ABSTRACT

A capacitor in a semiconductor memory device comprises a lower electrode on a substrate that is formed of a conductive metal oxide having a rutile crystalline structure, a titanium oxide dielectric layer on the lower electrode that has a rutile crystalline structure and includes impurities for reducing a leakage current, and an upper electrode on the titanium oxide dielectric layer. A method of forming a capacitor in a semiconductor device comprise steps of forming a lower electrode on a substrate that includes a conductive metal oxide having a rutile crystalline structure, forming a titanium oxide dielectric layer on the lower electrode that has a rutile crystalline structure and impurities for reducing a leakage current, and forming an upper electrode on the titanium oxide dielectric layer.

### CLAIM OF PRIORITY

This application claims priority under 35 USC §119 to Korean Patent Application No. 2010-0113110, filed on Nov. 15, 2010 in the Korean Intellectual Property Office (KIPO), the contents of which are herein incorporated by reference in their entirety.

### BACKGROUND

1. Field

The inventive concept described herein generally relates to the field of semiconductor memory device fabrication and, more particularly, to the field of high dielectric constant materials.

2. Description of the Related Art

A semiconductor memory device such as a dynamic random access memory (DRAM) device includes a unit storage unit as a metal oxide semiconductor (MOS) transistor and a memory cell capacitor for storing data. With DRAM devices ever shrinking in size, a need exists for a dielectric material having high and stable dielectric constant.

### SUMMARY

In an embodiment of the inventive concept, a capacitor in a semiconductor memory device comprises a lower electrode on a substrate that is formed of a conductive metal oxide having a rutile crystalline structure, a titanium oxide dielectric layer on the lower electrode that has a rutile crystalline structure and includes impurities for reducing a leakage current, and an upper electrode on the titanium oxide dielectric layer.

In a further embodiment of the inventive concept, the lower electrode includes ruthenium oxide. The lower electrode has a circular pillar shape, an elliptical pillar shape or a polygonal pillar shape. The lower electrode has a thickness in a range of about 30 Å to about 500 Å. The impurities in the titanium oxide dielectric layer include at least one selected from the group consisting of aluminum (Al), silicon (Si), hafnium (Hf), and zirconium (Zr). A concentration of the impurities is in a range of about 0.1 to about 20.0 percent by atomic weight. The titanium oxide dielectric layer has a thickness in a range of 30 to 150 Å. The upper electrode includes a conductive metal oxide having a rutile crystalline structure. The conductive metal oxide is ruthenium oxide.

In an embodiment of the inventive concept, a method of forming a capacitor in a semiconductor device comprise steps of forming a lower electrode on a substrate that includes a conductive metal oxide having a rutile crystalline structure, forming a titanium oxide dielectric layer on the lower electrode that has a rutile crystalline structure and impurities for reducing a leakage current, and forming an upper electrode on the titanium oxide dielectric layer.

In further embodiment of the inventive concept, the lower electrode is formed using ruthenium oxide by a chemical vapor deposition (CVD) process or an atomic layer deposition (ALD) process. The step of forming lower electrode is performed at a temperature of about 200° C. to about 400° C. The step of forming the lower electrode includes steps of forming a mold layer having an opening on the substrate, forming a conductive metal oxide layer to fill the opening, planarizing the conductive metal oxide layer to form the lower electrode in the opening, and removing the mold layer. The step of forming a titanium oxide dielectric layer is performed by a CVD process or an ALD process using the lower electrode as a seed layer. The impurities include at least one selected from the group consisting of aluminum (Al), silicon (Si), hafnium (Hf), and zirconium (Zr). The titanium oxide dielectric layer has impurities of which concentration is in a range of about 0.1 to about 20.0 percent by atomic weight. The impurities are doped into the titanium oxide dielectric layer by in-situ process. The upper electrode is formed using a conductive metal oxide having a rutile crystalline structure. The step of forming the lower electrode further comprises a step of performing a heat treatment process at a temperature in a range of about 300° C. to about 600° C. under an atmosphere including oxygen. The step of forming the titanium oxide dielectric layer further comprises a step of performing a heat treatment process at a temperature in a range of about 300° C. to about 600° C. under an atmosphere including oxygen. The step of forming the upper electrode further comprises a step of a heat treatment process about the upper electrode at a temperature in a range of about 300° C. to about 600° C. under an atmosphere including oxygen.

In an embodiment of the inventive concept, a semiconductor memory device comprises a transistor in a supporting structure, a bit line structure configured to electrically connect to a first impurity region of the transistor, a pad configured to electrically connect to a second impurity region of the transistor. The semiconductor memory device further comprises a capacitor which includes a lower electrode configured to electrically connect to the pad that includes a conductive metal oxide having a rutile crystalline structure, a titanium oxide dielectric layer on the lower electrode that includes impurities for reducing a leakage current, and an upper electrode on the titanium oxide dielectric layer.

In further embodiment of the inventive concept, the lower electrode includes ruthenium oxide. The lower electrode has a thickness in a range of about 30 Å to about 500 Å.

In an embodiment of the inventive concept, a semiconductor memory device comprises a step of forming a selection transistor in a supporting structure, a step of forming a bit line structure electrically connecting a first impurity region of the transistor, a step of forming a pad electrically contacting a second impurity region of the selection transistor, a step of forming a lower electrode on the supporting structure that electrically connects the pad in the supporting structure and includes a conductive metal oxide having a rutile crystalline structure, a step of forming a titanium oxide dielectric layer on the lower electrode that has a rutile crystalline structure and includes impurities for preventing a leakage current, and a step of forming an upper electrode on the titanium oxide dielectric layer.

In further embodiment of the inventive concept, the lower electrode is formed using ruthenium oxide by a CVD process or an ALD process. The step of forming the titanium oxide dielectric layer includes a CVD process or an ALD process, and the titanium oxide dielectric layer has a crystalline structure same as that of the conductive metal oxide of the lower electrode.

In an embodiment of the inventive concept, a semiconductor memory device comprise a supporting structure having a transistor, a bit line, and a pad wherein the bit line is configured to electrically connect to a first impurity region of the transistor and the pad is configured to electrically connect to a second impurity region of the transistor. The semiconductor memory device further comprises that a capacitor which includes a lower electrode configured to directly contact the pad that includes a conductive metal oxide having a rutile crystalline structure, a titanium oxide dielectric layer on the lower electrode that has a rutile crystalline structure and includes impurities for reducing a leakage current, and an upper electrode on the titanium oxide dielectric layer.

In further embodiment of the inventive concept, the lower electrode includes ruthenium oxide. The lower electrode has a thickness in a range of about 30 Å to about 500 Å and is used as a seed layer for forming the titanium oxide dielectric layer.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a cross-sectional view illustrating a capacitor in accordance with example embodiments;

FIGS. 2 to 5 are cross-sectional views illustrating a method of forming a capacitor in accordance with example embodiments;

FIG. 6 is a cross-sectional view illustrating a semiconductor device including a capacitor in accordance with example embodiments;

FIGS. 7 to 12 are cross-sectional views illustrating a method of manufacturing a semiconductor device in accordance with example embodiments;

FIG. 13 is a cross-sectional view illustrating a semiconductor device including a capacitor in accordance with example embodiments;

FIGS. 14 to 17 are cross-sectional views illustrating a method of manufacturing a semiconductor device in accordance with example embodiments;

FIG. 18 is a graph illustrating equivalent oxide layer thicknesses and breakdown voltages of dielectric layers;

FIG. 19 is a block diagram illustrating a memory system in accordance with example embodiments;

FIG. 20 is a block diagram illustrating a memory system in accordance with example embodiments; and

FIG. 21 is a block diagram illustrating a memory system in accordance with example embodiments.

### DESCRIPTION OF THE EMBODIMENTS

Exemplary embodiments of the inventive concept will be described below in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. The sizes and relative sizes of layers and regions, in the drawings, may be exaggerated for clarity. Like numerals refer to like elements throughout.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a cross-sectional view illustrating a capacitor in accordance with example embodiments.

Referring to FIG. 1, a storage capacitor 200 for a semiconductor device according to one embodiment of the inventive concept may be formed on a supporting structure 10. The supporting structure 10 may include a semiconductor substrate and other structures thereon. For example, the semiconductor substrate may be a silicon (Si) substrate, a germanium (Ge) substrate, a silicon-germanium substrate, a silicon-on-insulator (SOI) substrate, a germanium-on-insulator (GOI) substrate, an aluminum oxide (AlOx) substrate, a titanium oxide (TiOx) substrate. These may be used alone or in a combination thereof. The other structures may include a metal layer and an insulation layer.

In example embodiments, the storage capacitor 200 may include a lower electrode 16, a titanium oxide (TiOx) dielectric layer 18 and an upper electrode 20. The lower electrode 16 may include ruthenium oxide (RuOx) having a rutile crystalline structure. The titanium oxide dielectric layer 18 may be doped with impurities. The titanium oxide dielectric layer 18 may have a rutile crystalline structure and may be deposited using the lower electrode 16 as a seed layer. As a result, the titanium oxide dielectric layer 18 may have a crystalline structure substantially the same as or substantially similar to that of the lower electrode 16. The upper electrode 20 may be formed on the titanium oxide dielectric layer 18.

The lower electrode 16 may have various pillar shapes. For example, the shapes may be a substantially circular pillar shape, a substantially elliptical pillar shape, or a substantially polygonal pillar shape. The lower electrode 16 may have a thickness in a range of about 30 Å to about 500 Å. Alternatively, the thickness of the lower electrode 16 may be in a range of about 30 Å to about 100 Å.

The ruthenium oxide (RuOx) layer of the lower electrode 16 may be formed by various deposition methods. For example, the deposition methods may include a chemical vapor deposition (CVD) process and an atomic layer deposition (ALD) process. The ruthenium oxide (RuOx) layer may also be formed by oxidizing a ruthenium (Ru) layer after forming the ruthenium (Ru) layer on the supporting structure 200. The ruthenium oxide formed by the CVD process or the ALD process may have a rutile crystalline structure substantially having no lattice defects and/or few lattice defects therein, and as a result, the ruthenium oxide (RuOx) layer formed by the CVD or ALD processes may have an electrical conductivity substantially higher than that of the ruthenium oxide (RuOx) layer formed by oxidizing the ruthenium (Ru) layer.

Referring now to FIG. 1, the titanium oxide dielectric layer 18 may be formed on the lower electrode 16. The titanium oxide dielectric layer 18 may be uniformly deposited on the lower electrode 16. Accordingly, the titanium oxide dielectric layer 18 may enclose the lower electrode 16 to make contact with a side wall and an upper face of the lower electrode 16 when the lower electrode 16 has the various pillar shapes.

When the lower electrode 16 has the rutile crystalline structure including substantially no lattice defects, the titanium oxide dielectric layer 18 may be grown using the lower electrode 16 as a seed layer, so that the titanium oxide dielectric layer 18 may also have the rutile crystalline structure having substantially no lattice defects. The titanium oxide dielectric layer 18 may have a crystalline structure substantially the same as or substantially similar to that of the lower electrode 16.

When the titanium oxide dielectric layer 18 has a thickness above about 150 Å, defects may be generated in the rutile crystalline structure during a growth of the titanium oxide dielectric layer 18, so that a dielectric constant of the titanium oxide dielectric layer 18 may decrease. The titanium oxide dielectric layer 18 may start to have defects when its thickness is higher than about 150 Å. Meanwhile, when the titanium oxide dielectric layer 18 has a thickness below about 30 Å, the titanium oxide dielectric layer 18 may have a leakage current. Accordingly, the titanium oxide dielectric layer 18 of which thickness is between about 30 Å and about 150 Å may have electrical characteristics for a storage application in light of a dielectric constant and a leakage current. Alternatively, the titanium oxide dielectric layer 18 may a thickness in a range of about 50 Å to about 100 Å a for a storage application that requires a relatively high dielectric constant and a relatively low leakage current. The titanium oxide dielectric layer 18 may be doped with impurities. The impurities may include aluminum (Al), silicon (Si), hafnium (Hf), zirconium (Zr). These impurities may be doped alone or in a combination thereof. The titanium oxide layer 18 doped with those impurities may considerably reduce a leakage current compared to a titanium oxide layer without those impurities at the same thickness. According to example embodiments, the impurities may be symmetrically or asymmetrically doped in the titanium oxide dielectric layer 18. That is, a distribution of the impurities in the titanium oxide dielectric layer 18 may be symmetrical or asymmetrical. The titanium oxide dielectric layer 18 doped with impurities may have a dielectric constant above about 50 when the titanium oxide dielectric layer has a thickness above about 40 Å.

As a concentration of the impurities in the titanium oxide dielectric layer 18 increases, a dielectric constant of the titanium oxide dielectric layer 18 may decrease. For above about 20.0 percent by atomic weight based on a total atomic weight of the titanium oxide dielectric layer 18, the titanium oxide dielectric layer 18 may have undesirably low dielectric constant. Meanwhile, for below 0.1 percent by atomic weight, the amount of impurities may not have substantial effect on reducing a leakage current. Therefore, the impurity concentration of the titanium oxide dielectric layer 18 may be a range of about 0.1 to about 20.0 percent by atomic weight based on the total atomic weight of the titanium oxide dielectric layer 18. Alternatively, the titanium oxide dielectric layer 18 may have an impurity concentration in a range of about 0.1 to about 10.0 percent by atomic weight. For example, the titanium oxide dielectric layer 18 may have an aluminum concentration in a range of about 0.1 to about 10.0 percent by atomic weight based on the total atomic weight of the titanium oxide dielectric layer 18.

The upper electrode 20 may include a conductive metal oxide having a rutile crystalline structure. The upper electrode 20 may have the rutile crystalline structure and may be formed using the titanium oxide dielectric layer 18 as a seed layer. Alternatively, the rutile crystalline structure of the upper electrode 20 may be formed without using the titanium oxide dielectric layer 18 as a seed layer.

For example, the upper 20 electrode may include ruthenium oxide. Here, ruthenium oxide in the upper electrode 20 may be substantially the same as or substantially similar to that of the lower electrode 16. When the upper electrode 20 includes the metal oxide having the rutile crystalline structure, the crystalline structure of the upper electrode 20 may affect the crystalline structure of the titanium oxide dielectric layer 18 in a top-down mechanism. For example, when the upper electrode 20 has the rutile crystalline structure without any substantial crystalline defects, the titanium oxide dielectric layer 18 contacting the upper electrode 20 may be cured even though the titanium oxide dielectric layer 18 has some crystalline defects by the top-down mechanism.

The upper electrode 20, alternatively, may include a noble metal, a refractory metal, a refractory metal nitride, and a conductive oxide. These may be used alone or in a combination thereof. The noble metal in the upper electrode 20 may include ruthenium (Ru), platinum (Pt), and iridium (Ir). The refractory metal nitride in the upper electrode 20 may include titanium nitride (TiNx), tantalum nitride (TaNx), and tungsten nitride (WNx). Further, the conductive oxide in the upper electrode 20 may include iridium oxide (IrOx), strontium ruthenium oxide (SrRuxOy).

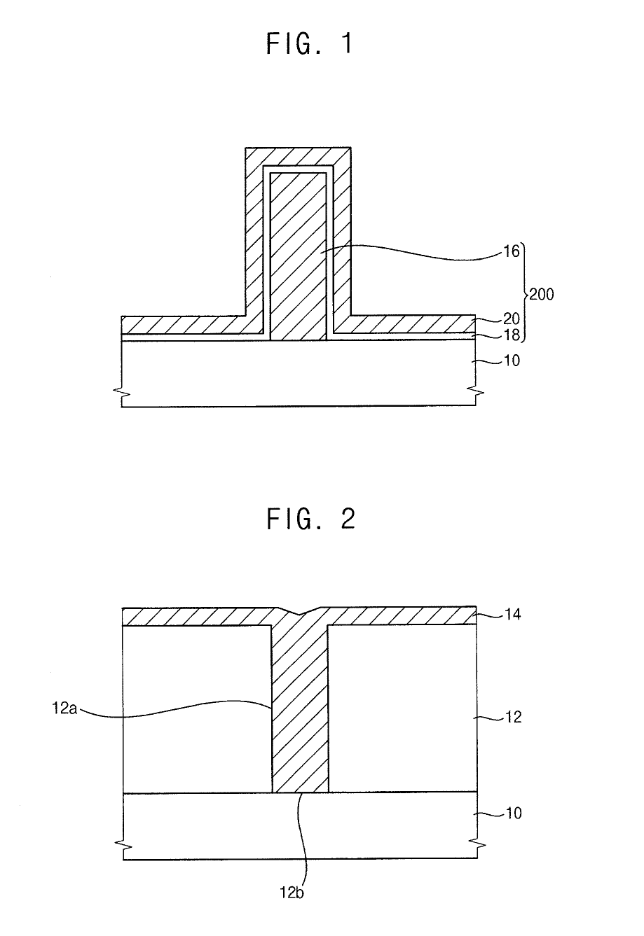

FIGS. 2 to 5 are cross-sectional views illustrating a method of forming the storage capacitor of FIG. 1. However, the method in FIGS. 2 to 5 may form other storage capacitors having various structures. For example, the structures may include a plate structure, a cylindrical structure, and a crown structure.

Referring to FIG. 2, a mold layer 12 may be formed on a supporting structure 10. The mold layer 12 may be formed of an insulating material including silicon oxide and silicon oxynitride, using various deposition methods including a spin coating process, a CVD process, a plasma enhanced chemical vapor deposition (PECVD) process, and a high density plasma-chemical vapor deposition (HDP-CVD) process. For example, the mold layer 12 may be formed using a material including silicon such as undoped silicate glass (USG), spin on glass (SOG), tetra ethyl ortho silicate (TEOS), plasma enhanced-TEOS (PE-TEOS), HDP-CVD oxide, flowable oxide (FOX), fluoro silicate glass (FSG), phosphor silicate glass (PSG), and boro-phosphor silicate glass (BPSG).

By partially etching the mold layer 12, an opening may 12a be formed through the mold layer 12. The opening 12a may expose a predetermined portion 12b of the supporting structure 10. The opening 12a may have a diameter below about 500 Å, having a contact hole shape or a via hole shape. A ruthenium oxide layer 14 may be formed on the mold layer 12 and the exposed portion 12b of the supporting structure 10 to fill the opening 12a of the mold layer 12. The ruthenium oxide layer 14 may have a thickness completely filling the opening 12a. The ruthenium oxide layer 14 may have a rutile crystalline structure and a desired conductivity.

The amount of lattice defects generated in the ruthenium oxide layer 14 may depend on a process of forming the ruthenium oxide layer 14. The amount of lattice defects may affect a dielectric constant of a titanium oxide dielectric layer 18 (see FIG. 4) formed on the ruthenium oxide layer 14 because the ruthenium oxide layer 14 is used as a seed layer for forming the titanium oxide dielectric layer 18. For example, the process for forming the ruthenium oxide layer 14 may include a chemical vapor deposition (CVD) process or an atomic layer deposition (ALD) process. With those processes, the ruthenium oxide layer 14 may be formed in a range of about 200° C. to about 400° C. to have a desired crystalline structure.

In formation of the ruthenium oxide layer 14, a gas including oxygen and a source gas including an organic metal compound that contains ruthenium (Ru) may be used as reaction gases. The gas containing oxygen may include an oxygen (O₂) gas, an ozone (O₃) gas, and a water (H₂O) vapor. The ruthenium oxide layer 14 may be obtained by a pulsed CVD process or a cyclic CVD process in which the reaction gases may be pulsed alternately. The source gas containing the organic metal compound containing ruthenium may include Ru(EtCp)₂, RuCp(i-PrCp), Ru(DER)₂, and Ru(DMPD)(EtCp). These may be used alone or in a combination thereof.

In some example embodiments, a source gas including an organic metal compound containing ruthenium may be introduced into a reaction chamber. After an absorption film including ruthenium may be formed on the exposed portion of the supporting structure 10 and the mold layer 12, a remaining source gas including the organic metal compound may be removed from the reaction chamber by purging the remaining source gas. Then, a gas including oxygen may be provided onto the absorption film formed on the substrate 10 and the mold layer 12 in the reaction chamber. The ruthenium oxide film 14 may be formed on the supporting structure 10 and the mold layer 12 by reacting the gas including oxygen with the absorption film including ruthenium. Then, a remaining gas including oxygen may be removed from the reaction chamber by purging the reaction chamber. The ruthenium oxide layer 14 may be formed on the substrate 10 and the mold layer 12 by an ALD process which includes a plurality of cycles having introducing the source gas including the organic metal compound containing ruthenium, primarily purging the reaction chamber, introducing the gas including oxygen, and secondarily purging the reaction chamber.

According to example embodiments, the ruthenium oxide layer 14 obtained by the CVD process or the ALD process may be controlled to have process conditions for forming a rutile crystalline structure. The ruthenium oxide layer 14 obtained by the CVD process or the ALD process may have lattice defects considerably lower than that of a ruthenium oxide layer formed by a physical vapor deposition (PVD) process or obtained by oxidizing a ruthenium layer.

In some example embodiments, after forming the ruthenium oxide layer 14 on the exposed portion of the supporting structure 10 and the mold layer 12, the ruthenium oxide layer 14 formed by those CVD processes may be further subject to a heat treatment to cure lattice defects in the ruthenium oxide layer 14. The heat treatment process may be carried out at a temperature in a range of about 300° C. to about 600° C. under an atmosphere including oxygen.

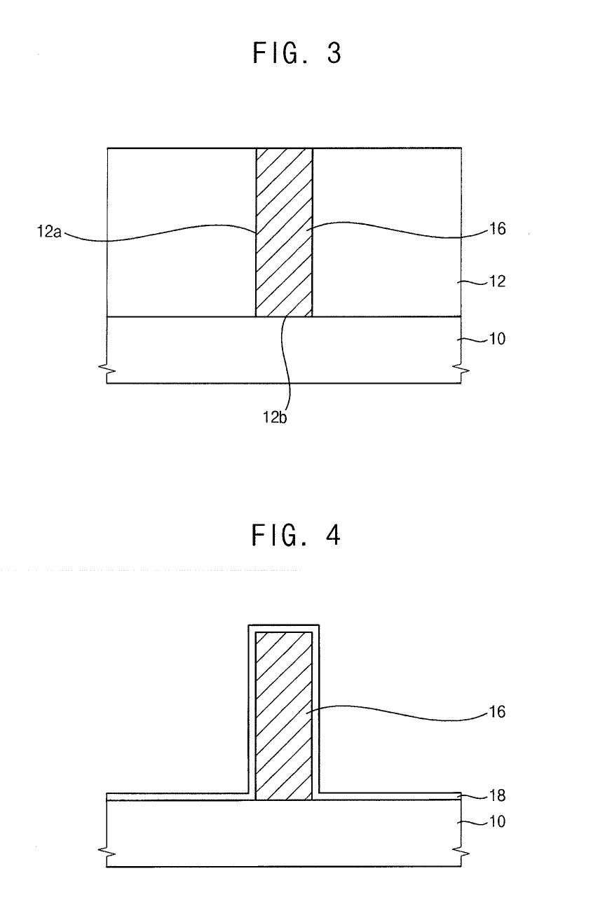

Referring to FIG. 3, a lower electrode 16 may be formed from the ruthenium oxide layer 14. The ruthenium oxide layer 14 may be partially removed until a surface of the mold layer 12 may be exposed. The ruthenium oxide layer 14 may be partially removed by a chemical mechanical polishing (CMP) process and/or an etch-back process. When the ruthenium oxide layer 14 is partially removed, a lower electrode 16 may be formed in the opening 12a. The lower electrode 16 may contact the exposed portion of the supporting structure 10. The lower electrode 16 may have a shape depending on a shape of the opening 12a of the mold layer 12. For example, the lower electrode 16 may have various pillar shapes including a substantially circular pillar shape, a substantially elliptical pillar shape, and a substantially polygonal pillar shape.

The exposed mold layer 12 may be removed from the substrate 10 using a wet etching process or a dry etching process. Thus, a side wall and an upper face of the lower electrode 16 may be exposed.

Referring to FIG. 4, a titanium oxide dielectric layer 18 may be formed on the lower electrode 16. Impurities may be doped into the titanium oxide dielectric layer 18 while forming the titanium oxide dielectric layer 18. That is, the impurities may be included in the titanium oxide layer 18 in-situ. Alternatively, the impurities may be doped into the titanium oxide layer 18 after forming the titanium oxide layer 18 on the lower electrode 16. The titanium oxide layer 18 may have a rutile crystalline structure substantially the same as or substantially similar to that of the lower electrode 16. The titanium oxide dielectric layer 18 may be formed using the lower electrode 16 as a seed layer by a CVD process or an ALD process. In this case, the titanium oxide dielectric layer 18 may be formed at a relatively low temperature in a range of about 200° C. to about 400° C.

Titanium oxide generally has three types of crystalline structures such as an anatase crystalline structure, a rutile crystalline structure, and a brookite crystalline structure. The titanium oxide has different dielectric constants depending on the structure type. For example, titanium oxide of an anatase crystalline structure may have a relatively low dielectric constant in a range of about 20 to about 30, whereas titanium oxide of a rutile crystalline structure may have a relatively high dielectric constant in a range of about 90 to about 170. Additionally, lattice defects existed in titanium oxide may adversely affect the dielectric constant of titanium oxide.

Generally, a titanium oxide layer, formed at a temperature below about 700° C., may have an anatase crystalline structure that has the relatively low dielectric constant. However, according to the exemplary embodiments, a titanium oxide layer may be formed on a ruthenium oxide layer having a rutile crystalline structure at a relatively low temperature of about 200° C. to about 400° C. Further, there may not be required an additional thermal treatment process that could cause a phase transition of the titanium oxide layer to have anatase crystalline structure.

According to example embodiments, when a ruthenium oxide layer served as the lower electrode 16 is formed by the CVD process or the ALD process, the ruthenium oxide layer may have substantially no lattice defects or few lattice defects therein, so that the titanium oxide dielectric layer 18 may have substantially no lattice defects or few lattice defects by using a ruthenium oxide layer of the lower electrode 16 as a seed layer for forming the titanium oxide dielectric layer 18. Thus, the titanium oxide dielectric layer 18 may have a high dielectric constant above about 100.

The titanium oxide dielectric layer 18 may not have a desired rutile crystalline structure substantially the same as or substantially similar to that of the lower electrode 16 where thickness of the titanium oxide dielectric layer 18 exceeds a specific thickness. Therefore, the titanium oxide dielectric layer 18 may have a low dielectric constant, which may be lower than a desired high dielectric constant. The specific thickness of the titanium oxide dielectric layer 18 may be in a range of about 30 Å to about 150 Å.

In example embodiments, impurities doped into the titanium oxide dielectric layer 18 may include aluminum (Al), silicon (Si), hafnium (Hf), and zirconium (Zr). These impurities may be used alone or in a combination thereof. In this case, the impurities may be doped into the titanium oxide dielectric layer 18 while forming the titanium oxide dielectric layer 18 on the lower electrode 16. That is, the impurities may be added into the titanium oxide layer 18 in-situ. For example, the impurities may be doped by introducing a vapor-phased impurity source gas including aluminum, silicon, hafnium and/or zirconium while forming the titanium oxide dielectric layer 18 on the lower electrode 16. The impurity source gas may be introduced into a reaction chamber through a different gas supplying line from a gas supplying line for providing a reaction gas for forming the titanium oxide dielectric layer 18 into the reaction chamber. The impurity source gas and the reaction gas may be simultaneously provided into the reaction chamber, or the impurity source gas may be introduced into the reaction chamber after the reaction gas is provided. The titanium oxide dielectric layer 18 may have impurities, their concentration being in a range of about 0.1 to about 20.0 percent by atomic weight based on a total atomic weight of the titanium oxide dielectric layer 18.

In some example embodiments, the titanium oxide dielectric layer 18 may be formed by a pulsed chemical vapor deposition process. That is, the titanium oxide dielectric layer 18 may be formed using a gas including oxygen and a source gas including an organic metal compound containing titanium as reaction gases, and by alternately pulsing the gas including oxygen and the source gas. For example, the organic metal compound source may include Ti(OC₃H₇)₄. Impurities may be doped into the titanium oxide dielectric layer 18 while alternately pulsing the reaction gases. Alternatively, the impurities may be doped into the titanium oxide layer 18 after pulsing of the reaction gases.

In some example embodiments, the titanium oxide dielectric layer 18 may be formed by the ALD process. Here, a source gas including an organic metal compound containing titanium may be introduced into a reaction chamber. The source gas is absorbed on the lower electrode 16 and an absorbed layer including titanium is formed on the lower electrode 16. The remaining source gas may be purged from the reaction chamber. A gas including oxygen may be provided onto the absorbed layer in the reaction chamber, and a titanium oxide film may be formed on the lower electrode 16 by reacting the gas including oxygen with the absorbed layer including titanium. Then, the remaining gas including oxygen may be purged from the reaction chamber. The titanium oxide dielectric layer 18 may be formed by performing cycles of the ALD process wherein the cycle of the ALD process includes introducing the source gas including the organic metal compound containing titanium, purging the remaining source gas from the reaction chamber, introducing the gas including oxygen, and purging the remaining gas including oxygen from the reaction chamber.

With the exemplary embodiments of the pulsed chemical vapor deposition or ALD deposition, the titanium oxide dielectric layer 18 having the rutile crystalline structure and the relatively high dielectric constant may be formed at a relatively low temperature in a range of about 200° C. to about 400° C. using the lower electrode 16 as a seed layer. That is, without requiring a high temperature process executed at a high temperature above about 700° C., the titanium oxide dielectric layer 18 having desired characteristics may be formed on the lower electrode 16. Therefore, an underlying layer and/or an underlying structure on the substrate 10 may not have thermal damages while forming the titanium oxide dielectric layer 18.

In some examplary embodiments, after forming the titanium oxide dielectric layer 18, a heat treatment process may be additionally performed about the titanium oxide dielectric layer 18. The heat treatment process may be carried out for curing the titanium oxide dielectric layer 18 so as to improve characteristics thereof without a crystallization of ingredients in the titanium oxide dielectric layer 18. Therefore, the heat treatment process may be executed at a temperature substantially higher than that of the process of forming the titanium oxide dielectric layer 18. For example, the heat treatment process may be carried out at a temperature substantially lower than about 600° C. The heat treatment process may be performed under an atmosphere including an inactive gas or oxygen. The heat treatment process may be carried out for a time below about 500 minutes. For example, the heat treatment process may be executed for less than about 310 minutes.

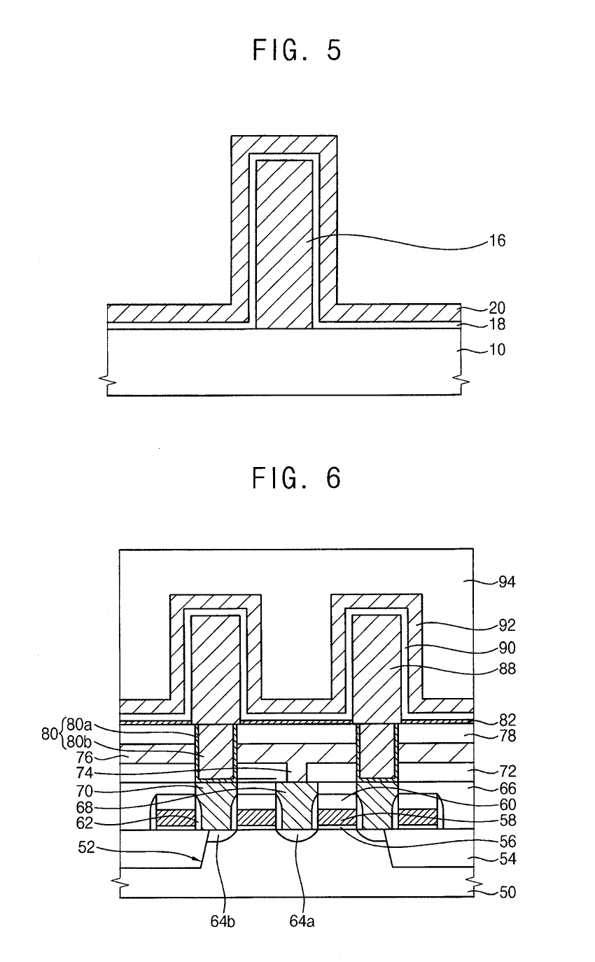

Referring FIG. 5, an upper electrode 20 may be formed on the titanium oxide dielectric layer 18. The upper electrode 20 may be uniformly formed on a profile of the titanium oxide dielectric layer 18. The upper electrode 20 may be formed by depositing conductive metal oxide having a rutile crystalline structure on the titanium oxide dielectric layer 18. For example, the conductive metal oxide may include ruthenium oxide, iridium oxide (IrOx), and strontium ruthenium oxide (SrRuxOy).

In some examplary embodiments, the upper electrode 20 may be formed using metal. For example, the metal may include noble metal, refractory metal, and refractory metal nitride.

Examples of the noble metal in the upper electrode 20 may include ruthenium (Ru), platinum (Pt), and iridium (Ir). Examples of the refractory metal nitride in the upper electrode 20 may include titanium nitride (TiNx), tantalum nitride (TaNx), and tungsten nitride (WNx).

In some examplary embodiments, after the upper electrode 20 is formed, a heat treatment process may be additionally performed to improve electrical characteristics of the upper electrode 20. The heat treatment process may be carried out at a temperature of about 300° C. to about 600° C. under an atmosphere including oxygen.

According to the examplary embodiments, a lower electrode 16 including ruthenium oxide having no lattice defects and/or few lattice defects may be obtained by a CVD process or an ALD process. Therefore, a titanium oxide dielectric layer 18, having a rutile crystalline structure caused by that of the lower electrode and a relatively high dielectric constant, may be formed on the lower electrode 16. Further, impurities may be doped into the titanium oxide dielectric layer 18 so that a storage capacitor including the titanium oxide dielectric layer may have a high dielectric constant and a relatively low leakage current through the titanium oxide dielectric layer 18.

FIG. 6 is a cross-sectional view illustrating a semiconductor device using the storage capacitor structure of FIG. 1 as a memory cell.

Referring to FIG. 6, an isolation region and an active region of a substrate 50 may be defined by forming an isolation layer 54 on the substrate 50. A switching device such as a metal oxide semiconductor (MOS) transistor may be provided on the substrate 50. For example, the MOS transistor may have a planar type as illustrated in the FIG. 6. Alternatively, the MOS transistor may include a buried gate structure, or a recessed gate structure.

A first insulating interlayer 66 may be formed on the substrate 50 to cover the MOS transistor. A first pad 68 and a second pad 70 may be disposed through the first insulating interlayer 66 to make contact with impurity regions 64a and 64b provided on the substrate 50.

A second insulating interlayer 72 may be formed on the first insulating interlayer 66, the first pad 68, and the second pad 70. A bit line contact 74 may be formed through the second insulating interlayer 72 to contact the first pad 68. A bit line 76 may be formed on the second insulating interlayer 72, contacting the bit line contact 74.

A third insulating interlayer 78 may be formed on the second insulating interlayer 72. A storage node contact 80 may pass through the second and the third insulating interlayers 72 and 78 to make contact with the second pad 70.

In examplary embodiments, the storage node contact 80 may include metal or conductive metal oxide. The storage node contact 80 may include a barrier metal layer 80a and a conductive layer 80b sequentially formed on the second pad 70. For example, the barrier metal layer 80a may include a titanium film and a titanium nitride film. The conductive layer 80b may include a conductive metal oxide such as ruthenium oxide film or a metal layer such as ruthenium (Ru). Since the storage node contact 80 may include metal, a contact resistance between the second pad 70 and the storage node contact 80 may be reduced.

A storage capacitor including a lower electrode 88, a titanium oxide dielectric layer 90 and an upper electrode 92 may be formed on the storage node contact 80.

In examplary embodiments, the lower electrode 88 may have various pillar shapes, for example, a substantially circular pillar shape, a substantially elliptical pillar shape, and a substantially polygonal pillar shape. The lower electrode 88 may further have a relatively small thickness. For example, the lower electrode 88 may have a small thickness less than about 500 Å. In one examplary embodiment, the thickness of the lower electrode 88 may be in a range of about 30 Å to about 100 Å. The lower electrode 88 may include ruthenium oxide formed by a CVD process or an ALD process. For example, the lower electrode 88 may include ruthenium oxide formed by the CVD process or the ALD process to have a rutile crystalline structure.

In some examplary embodiments, the titanium oxide dielectric layer 90 may be formed on the lower electrode 88. The titanium oxide dielectric layer 90 may be uniformly formed along a profile of the lower electrode 16 to enclose the lower electrode 88. That is, the titanium oxide dielectric layer 90 may surround the lower electrode 88 to make contact with a side wall and an upper face of the lower electrode 88. When the lower electrode 88 has the rutile crystalline structure that has substantially no lattice defects, the titanium oxide dielectric layer 90 may grow from the lower electrode 88 to have a rutile crystalline structure substantially the same as or substantially similar to that of the lower electrode 88. The titanium oxide dielectric layer 90 may have a thickness in a range of about 30 Å to about 150 Å. Alternately, the titanium oxide dielectric layer 90 may have a thickness of about 30 Å to about 100 Å, such that the titanium oxide dielectric layer 90 may ensure desired characteristics such as a relatively high dielectric constant, and a relatively low leakage current. When the titanium oxide dielectric layer 90 has the rutile crystalline structure caused by that of the lower electrode 88, the titanium oxide dielectric layer 90 may have a relatively high dielectric constant above about 100.

In some examplary embodiments, the titanium oxide dielectric layer 90 may include doped impurities therein. For example, the impurities may include aluminum, silicon, hafnium, and zirconium. These may be used alone or in a combination thereof. The impurity concentration in the titanium oxide dielectric layer 90 may be a range of about 0.1 to about 20.0 percent by atomic weight based on a total atomic weight of the titanium oxide dielectric layer 90.

The upper electrode 92 may include a conductive metal oxide having a rutile crystalline structure. In an examplary embodiment, the upper electrode 92 may include a conductive metal oxide such as ruthenium oxide, iridium oxide, and strontium ruthenium oxide. Here, ruthenium oxide in the upper electrode 20 may be substantially the same as or substantially similar to that of the lower electrode 16. Alternatively, the upper electrode 92 may include noble metal, refractory metal, and refractory metal nitride. For example, noble metal in the upper electrode 92 may include ruthenium, platinum, and iridium. Refractory metal nitride in the upper electrode 92 may include titanium nitride, tantalum nitride, and tungsten nitride.

Referring now to FIG. 6, a plate electrode 94 may be formed on the upper electrode 92. The plate electrode 94 may have a level upper face to sufficiently cover the resultant structure. The plate electrode 94 may include polysilicon, and polysilicon doped with impurities.

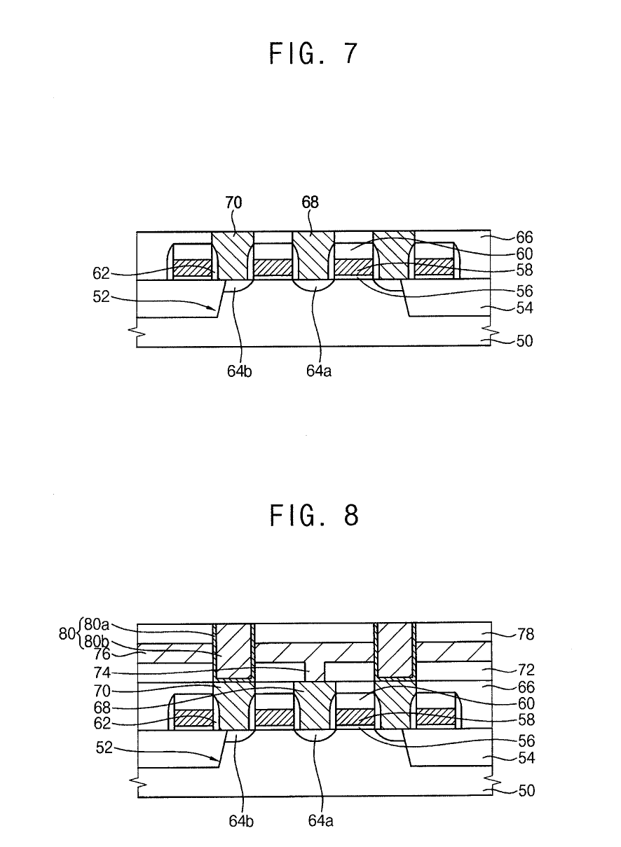

FIGS. 7 to 12 are cross-sectional views illustrating a method of manufacturing the semiconductor device of FIG. 6 in accordance with examplary embodiments of the inventive concept. However, the method illustrated in FIGS. 7 to 12 shall not be limited to manufacturing the device of FIG. 6 and may be used to manufacture various structures in accordance with the inventive concept.

Referring to FIG. 7, a pad oxide layer (not illustrated) and a silicon nitride layer (not illustrated) may be sequentially formed on a substrate 50. The substrate 50 may include a semiconductor substrate, a substrate having a semiconductor layer, a metal oxide substrate, etc. A photoresist pattern (not illustrated) may be formed on the silicon nitride layer. The photoresist pattern may expose a portion of the silicon nitride layer. The exposed portion of the silicon nitride layer and a portion of the pad oxide layer may be etched using the photoresist pattern as an etching mask, thereby forming a first hard mask pattern (not illustrated) on the substrate 50. The hard mask pattern may include a pad oxide layer pattern and a silicon nitride layer pattern. The hard mask pattern may expose a predetermined portion of the substrate 50 where an isolation layer 54 will be positioned.

The exposed portion of the substrate 50 may be etched using the first hard mask pattern as an etching mask, so that a trench 52 is formed on the substrate 50. The trench 52 may be filled by a silicon oxide layer (not illustrated) having a desired gap fill characteristic. The silicon oxide layer may be planarized by an etch-back process and/or a CMP process until the substrate 50 is exposed. The planarized silicon oxide layer in the trench 52 may be called as an isolation region. As a result, the substrate 50 may have an isolation region and an active region.

A gate insulation layer 56 may be formed on the substrate 50, and then a gate electrode 58 and a gate mask 60 may be sequentially formed on the gate insulation layer 56. Thus, a gate structure having the gate insulation layer 56, the gate electrode 58 and the gate mask 60 may be provided on the substrate 50.

After forming a spacer 62 on a side wall of the gate structure using silicon nitride, impurities may be implanted into portions of the substrate 50 adjacent to the gate structure using the gate structure and the spacer 62 as masks. Hence, a first impurity region 64a and a second impurity region 64b may be formed in the active region of the substrate 50. The first and the second impurity regions 64a and 64b may serve as source/drain regions of a MOS transistor.

A first insulating interlayer 66 may be formed on the substrate 50 to cover the gate structure. The first insulating interlayer 66 may have a thickness to sufficiently cover the gate structure. A first pad 68 and a second pad 70 may be formed through the first insulating interlayer 66. The first and the second pads 68 and 70 may electrically contact the first and the second impurity regions 64a and 64b, respectively.

Referring to FIG. 8, a second insulating interlayer 72 may be formed on the first insulating interlayer 66, the first pad 68 and the second pad 70. A bit line contact 74 may be formed through the second insulating interlayer 72. The bit line contact 74 may make contact with the first pad 68. Thus, the bit line contact 74 may be electrically connected to the first impurity region 64a through the first pad 68. Further, a bit line 76 may be formed on the second insulating interlayer 72 and the bit line contact 74. Therefore, the bit line 76 may also electrically connected to the first impurity region 64a through the first pad 68 and the bit line contact 74.

A third insulating interlayer 78 may be formed on the second insulating interlayer 72 and the bit line 76. The third insulating interlayer 78 may be formed using silicon oxide by a CVD process including a PECVD process, and an HDP-CVD process.

The third insulating interlayer 78 and the second insulating interlayer 72 may be partially etched to form an hole (not illustrated) that exposes an upper face of the second pad 70. A storage node contact 80 may be formed on the second pad 70 in the hole. In some example embodiments, after depositing a conductive material on the third insulating interlayer 78 to fill the hole, the deposited conductive material may be planarized until the third insulating interlayer 78 is exposed. Therefore, the storage node contact 80 filling the hole may be formed.

In example embodiments, a barrier metal layer (not illustrated) may be formed on the second pad 70, a side wall of the hole and the third insulating interlayer 78. A conductive layer including metal may be formed on the barrier metal layer (not illustrated) to fill the hole. The conductive layer and the metal barrier layer may be planarized until the third insulating interlayer 78 is exposed. For example, the barrier metal layer may include a titanium film and a titanium nitride film. Further, the conductive layer may include ruthenium, and ruthenium oxide.

The storage node contact 80 may make contact with the second pad 70. Hence, the storage node contact 80 may be electrically connected to the second impurity region 64b through the second contact pad 70.

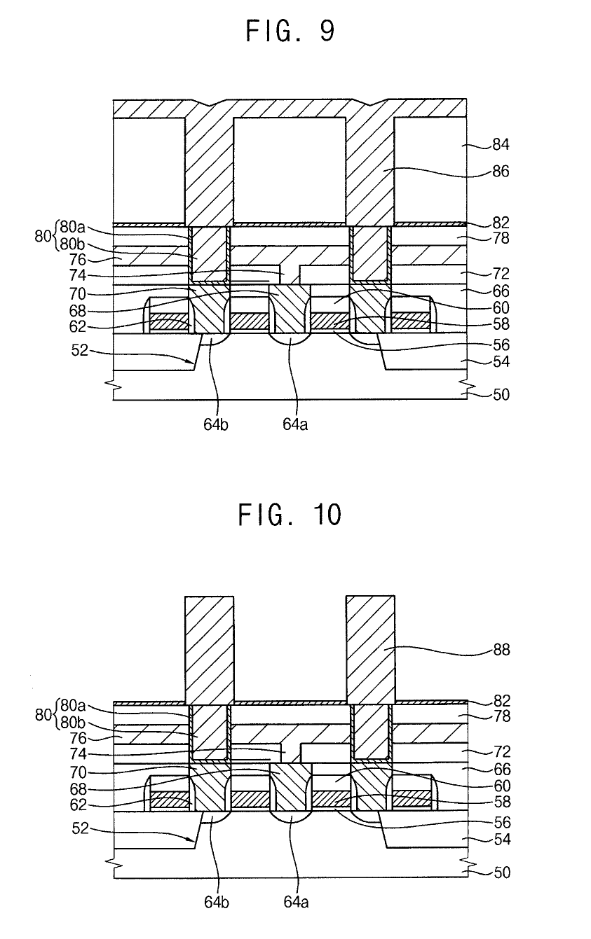

Referring to FIG. 9, an etch stop layer 82 may be formed on the third insulating interlayer 78 and the storage node contact 80. A mold layer 84 may be formed on the etch stop layer 82. The mold layer 84 and the etch stop 82 layer may be partially etched to expose an upper surface of the storage node contact 80. Thus, an opening may be formed through the mold layer 84 and etch stop layer 82. The opening may partially expose the upper surface of the storage node contact 80. Here, the opening may have a width larger than that of the storage node contact 80. Thus, a portion of the third insulating interlayer 78 adjacent to the storage node contact 80 may be exposed through the opening. The opening may have various shapes including a contact hole shape or a via hole shape.

A ruthenium oxide layer 86 may be formed on the mold layer 84 and the exposed portion of the storage node contact 80. The ruthenium oxide layer 86 may sufficiently fill the opening. The ruthenium oxide layer 86 may be formed by a CVD process or an ALD process, so that the ruthenium oxide layer 86 may have a rutile crystalline structure and a desired conductivity. The ruthenium oxide layer 86 may be formed by a process substantially the same as or substantially similar to that described with reference to FIG. 2.

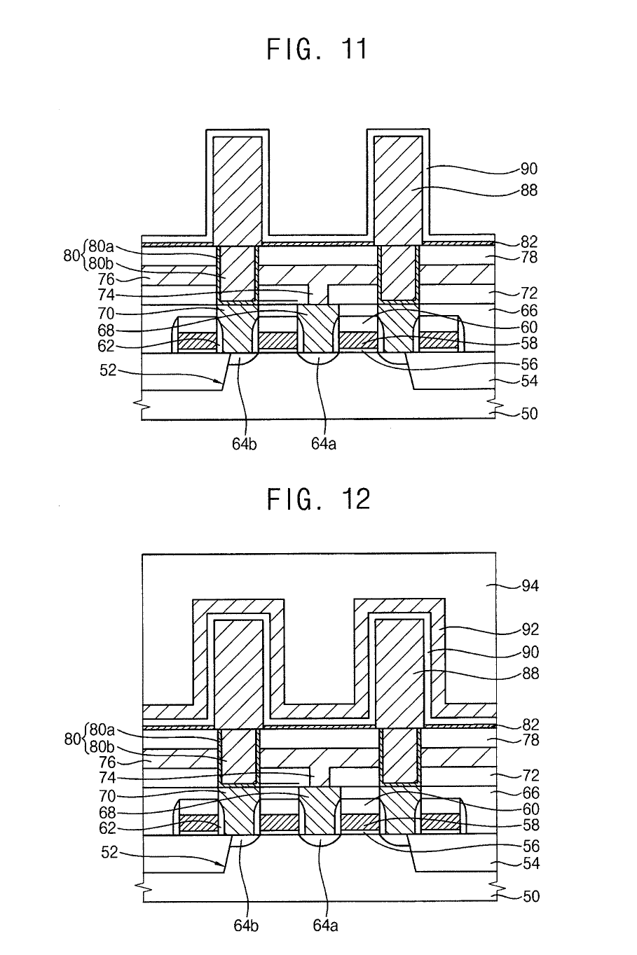

Referring to FIG. 10, a lower electrode 88 may be formed on the storage node contact 80 in the opening by planarizing the ruthenium oxide layer 86 of FIG. 9 by a CMP process and/or an etch back process. The planarization process may be performed until an upper surface of the mole layer 84 is exposed. After the planarization process, the mold layer 84 may be removed from the second stop layer 82 and the lower electrode 88. Thus, a sidewall and an upper face of the lower electrode 88 may be exposed over the etch stop layer 82. The mold layer 84 may be removed by a wet etching process and/or a dry etching process. The lower electrode 82 may have various structures having a shape such as a pillar shape, a cylindrical shape, and a crown shape. The lower electrode 88 may be electrically connected to the second impurity region 64a through the second pad 70 and the storage node contact 80.

Referring to FIG. 11, a titanium oxide dielectric layer 90 may be formed on the etch stop layer 82 and the lower electrode 88. Specifically, the titanium oxide dielectric layer 90 may enclose the lower electrode 88. In examplary embodiments, impurities may be added into the titanium oxide dielectric layer 90 while forming the titanium oxide dielectric layer 90 on the lower electrode 88. That is, the impurities may be included in the titanium oxide dielectric layer 90 by in-situ. Alternatively, the impurities may be doped into the titanium oxide dielectric layer 90 after forming the titanium oxide dielectric layer 90 on the lower electrode 88.

In examplary embodiments, the titanium oxide dielectric layer 90 may have a rutile crystalline structure substantially the same as or substantially similar to that of the lower electrode 88. Here, the titanium oxide dielectric layer 90 may be formed using the lower electrode 88 as a seed layer so that the titanium oxide dielectric layer 90 may have a crystalline structure substantially similar to that of the lower electrode 88. The titanium oxide dielectric layer 90 may be formed by a CVD process or an ALD process. The titanium oxide dielectric layer 90 may be formed by a process substantially the same as or substantially similar to that described with reference to FIG. 4.

Referring to FIG. 12, the upper electrode 92 including metal may be formed on the titanium oxide dielectric layer 90. In examplary embodiments, the upper electrode 92 may be formed using a conductive metal oxide having a rutile crystalline structure. For example, the upper electrode 92 may be formed using ruthenium oxide. The upper electrode layer 92 may be formed by a process substantially the same as or substantially similar to that described with reference to FIG. 5.

A plate electrode 94 may be formed on the upper electrode 92. The plate electrode 94 may be formed by depositing polysilicon or doped polysilicon on the upper electrode 92. Therefore, the storage capacitor may be provided over the substrate 50. Alternatively, a protection layer (not illustrated) may be formed on the upper electrode 92. The protection layer may have a planarized surface by a CMP process and/or an etch-back process.

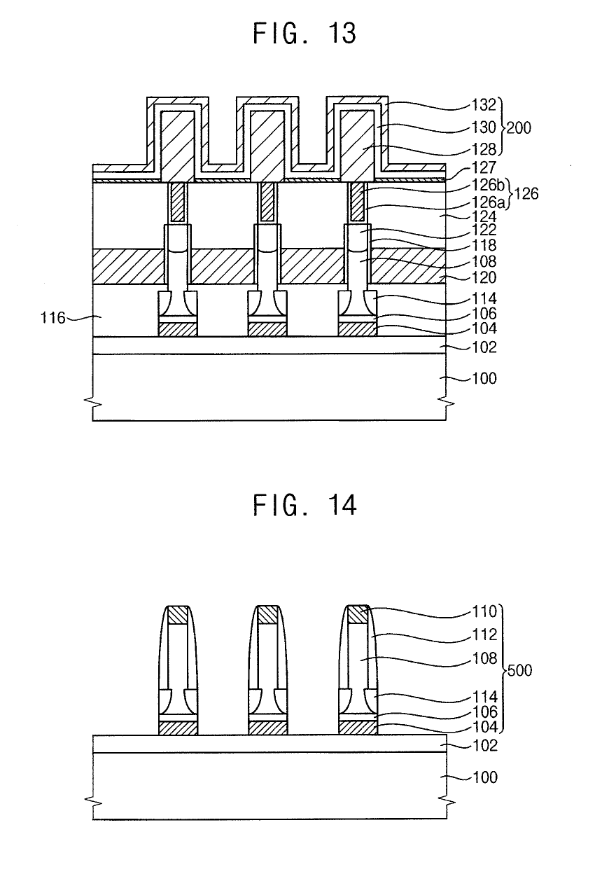

FIG. 13 is a cross-sectional view illustrating another semiconductor device including a storage capacitor structure of FIG. 1 in accordance with examplary embodiments of the inventive concept.

Referring to FIG. 13, the semiconductor device 200 may include a substrate 100, an insulation layer 102, a buried wiring 104 and a barrier layer pattern 106. The buried wiring 104 may have a line shape or a bar shape which extends in a first direction on the insulation layer 102. In examplary embodiments, the buried wiring 104 may serve as a bit line in the semiconductor device 200.

An active pattern 108 may correspond to an active region of the semiconductor device 100 of FIG. 12. The active pattern 108 may have a various pillar shape. For example, the active pattern 108 may have substantially circular pillar shapes, substantially elliptical pillar shapes, substantially polygonal pillar shapes, respectively. A transistor having a vertical channel may be formed on the active pattern 108. In examplary embodiment, the transistor may be a vertical channel transistor that has a channel region formed along a direction substantially perpendicular to the substrate structure. The transistor may include a gate electrode 120 surrounding the active pattern 108. For example, the gate electrode 120 may surround a central portion of the active pattern 108, so that a lower portion and an upper portion of the active pattern 108 may be exposed.

Here, a first insulating interlayer 116 may be formed on the insulation layer 102 to cover the lower portion of the active pattern 118. That is, the gate electrode 120 may be separated from the lower portion of the active pattern 108 by the first insulating interlayer 116.

A first impurity region 114 may be formed at a lower portion of the active pattern 108 and a second impurity region 122 may be formed at an upper portion of the active pattern 108. The lower portion of the active pattern 108 including the first impurity region 114 may have a width substantially larger than that of the central portion of the active pattern 108. Thus, the active pattern 108 may have a step between the central portion of the active pattern 108 and the lower portion of the active pattern 108 having the first impurity region 114.

A gate insulation layer 118 may be formed on a sidewall of the active pattern 108, enclosing the central and the upper portion of the active pattern 108. Further, the gate electrode 120 surrounding the active pattern 108 may be formed on the gate insulation layer 118. Thus, the gate insulation layer 118 may be interposed between the central portion of the active pattern 108 and the gate electrode 120. The gate electrode 120 may extend in a second direction substantially perpendicular to the first direction where the buried wiring 104 may extend. In examplary embodiments, the gate electrode 120 may serve as a word line of the semiconductor device.

The first insulating interlayer 116 may be formed on the insulation layer 102 to cover the buried wiring 104 and the lower portion of the active pattern 108 having the first impurity region 114. The first insulating interlayer 116 may partially enclose the central portion of the active pattern 108. Therefore, the gate electrode 120 may be separated from the first impurity region 114 by the first insulating interlayer 116.

A second insulating interlayer 124 may be formed on the first insulating interlayer 116 and the first transistors having the vertical channel. For example, the second insulating interlayer 124 may sufficiently cover the gate electrode 120 and the upper portion of the active pattern 108. Here, the second insulating interlayer 124 may have a flat upper surface. A pad 126 may be located through the second insulating interlayer 124. The pad 126 may make contact with the second impurity region 122 positioned at the upper portion of the active pattern 108.

The pad 126 may include metal or conductive metal oxide. In examplary embodiments, the pad 126 may include a barrier metal layer 126a and a conductive metal oxide layer 126b, or a barrier metal layer 126a and a metal layer 126b. For example, the barrier metal layer 126a may include titanium/titanium nitride. The conductive metal oxide layer 126b may include ruthenium oxide, and the metal layer 126b may include ruthenium. Thus, the pad 126 may include a material to reduce a contact resistance between the pad 126 and the second impurity region 122.

An etch stop layer 127 may be formed on the second insulating interlayer 124. In this case, the etch stop layer 127 is patterned to expose the pad 126. A storage capacitor having a lower electrode 128, a dielectric layer 130 and an upper electrode 132 may be formed on the pad 126. The storage capacitor may have a construction substantially the same as or substantially similar to that of the capacitor described with reference to FIG. 6. The lower electrode 128 may include ruthenium oxide having a rutile crystalline structure formed by an ALD process or a CVD process. The dielectric layer 130 may include titanium oxide ensuring no lattice defects and/or few lattice defects. The upper electrode 132 may include noble metal, refractory metal, refractory metal nitride and/or metal oxide having a desired conductivity and a rutile crystalline structure.

FIGS. 14 to 17 are cross-sectional views illustrating a method of manufacturing the semiconductor device of FIG. 13 in accordance with exemplary embodiments of the inventive concept.

Referring to FIG. 14, there is provided a preliminary active pattern 500 over a substrate 100. The preliminary active pattern may include a buried wiring 104, a barrier layer pattern 106, a first impurity region 114, an active pattern 108, a space 112 and mask pattern 110.

For the preliminary active pattern 500, an insulation layer 102 is formed on the substrate 100. A wiring layer (not illustrated) for the buried wiring 104 is formed on the insulation layer 102, and a buried layer (not illustrated) for the barrier layer pattern 106 is formed on the wiring layer.

With a hard mask pattern 110, a spacer 112 may be formed on an upper sidewall of the preliminary active pattern. The spacer 112 may be formed using nitride such as silicon nitride or oxynitride such as silicon oxynitride. Impurities may be implanted into the preliminary active pattern using the spacer 112 as an implantation mask, so that a first impurity region 114 may be formed at the lower portion of the preliminary active pattern.

With the hard mask pattern 110 and the spacer 112 as etching masks, the barrier layer and the buried wiring layer may be patterned to form the barrier layer pattern 106 and the buried wiring 104 on the insulation layer 102. The buried wiring 104 may have a line shape or a bar shape extending in a first direction. The buried wiring 104 may be electrically connected to the first impurity region 114. The buried wiring 104 may serve as a bit line of the semiconductor device.

Referring to FIG. 15, there may be provided an active pattern 108. The active pattern 108 may include a first impurity region 114 and a second impurity region 118. For the formation of the active pattern 108, the spacer 112 of FIG. 14 may be removed from the preliminary active pattern 500 of FIG. 14. A preliminary insulating interlayer (not illustrated) is formed on the insulation layer 102, covering the active pattern 108. The preliminary insulating interlayer may be partially etched to form a first insulating interlayer 116 and to expose a sidewall of the active pattern 118. The first insulating interlayer 116 may cover a lower portion of the active pattern 108 having the first impurity region 114, and partially cover a central portion of the active pattern 108. As a result, the first impurity region 114 may also be covered with the first insulating interlayer 116.

A gate insulation layer 118 may be formed on the side wall of the active pattern 108. Because the first insulating interlayer 116 covers the first impurity region 114, the gate insulation layer 118 may be separated from the first impurity region 114.

A conductive layer (not illustrated) may be formed on the first insulating interlayer 116 to form a gate electrode 120. After forming a mask pattern (not illustrated) on the conductive layer, the conductive layer may be partially removed to form the gate electrode 120 on the first insulating interlayer 116. The gate electrode 120 may have a line shape or a bar shape extending along a second direction substantially perpendicular to the first direction. The gate electrode 120 may surround the gate insulation layer 118 on the central portion of the active pattern 108 and as a result, an upper portion of the gate insulation layer 118 may be exposed without contacting the gate electrode 120.

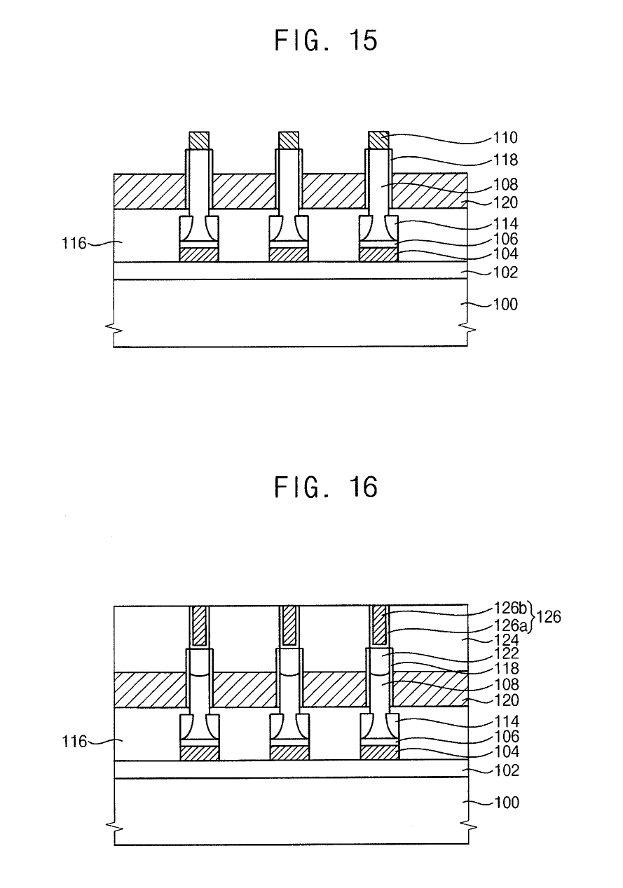

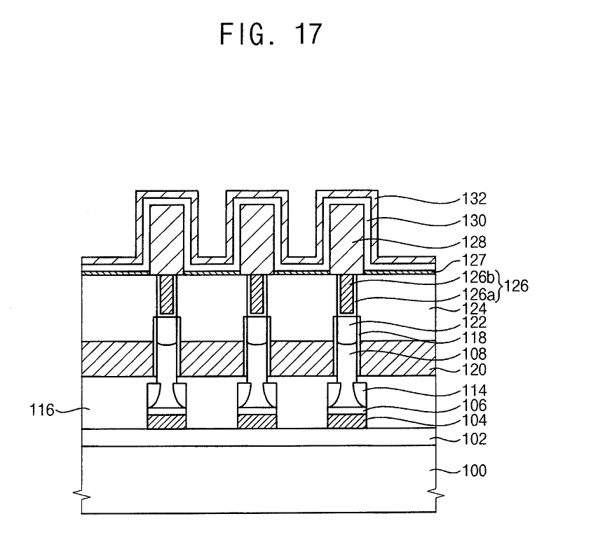

Referring to FIG. 16, the hard mask pattern 110 of FIG. 15 may be removed to expose an upper surface of the active pattern 108. A second impurity region 122 may be formed by doping impurities into the upper portion of the active pattern 108. Thus, a vertical channel transistor including the gate insulation layer 118, the gate electrode 120, the first impurity region 114 and the second impurity region 122 may be formed over the substrate 100.

A second insulating interlayer 124 may be formed on the first insulating interlayer 116 and the gate electrode 120 to cover the vertical channel transistor. A pad 126 may be formed through the second insulating interlayer 124. The pad 126 may connect to the upper surface of the active pattern 108 where the second impurity region 122 is positioned. The pad 126 may include metal or conductive metal oxide. In exemplary embodiments, the pad 126 may be obtained by successively forming a ruthenium layer 126b and a barrier metal layer 126a including titanium/titanium nitride on the upper portion of the active pattern 108. Alternatively, the pad 126 may be obtained by forming a ruthenium oxide layer 126b and a barrier metal layer 126a including titanium/titanium nitride on the upper portion of the active pattern 108.

Referring to FIG. 17, an etch stop layer 127 may be formed on the pad 126 and the second insulating interlayer 124. The etch stop layer 127 may be patterned to expose an upper surface of the pad 126. Here, a portion of the second insulating interlayer 124 adjacent to the pad 126 may also be exposed. A storage capacitor including a lower electrode 128, a dielectric layer 130 and an upper electrode 132 may be formed on the pad 126 and the exposed portion of the second insulating interlayer 124. The processes of forming the capacitor may be substantially the same as or substantially similar to those described with reference to FIGS. 9 to 12.

According to exemplary embodiments, a storage capacitor ensuring a desired high capacitance and improved electrical characteristics may be employed in a semiconductor device. A lower electrode 128 of the capacitor may include ruthenium oxide that has a rutile crystalline structure. A dielectric layer of the capacitor may include titanium oxide that also has a rutile crystalline structure. Further, an upper electrode of the capacitor may include a conductive material.

### Evaluation of Electrical Characteristics of Capacitors

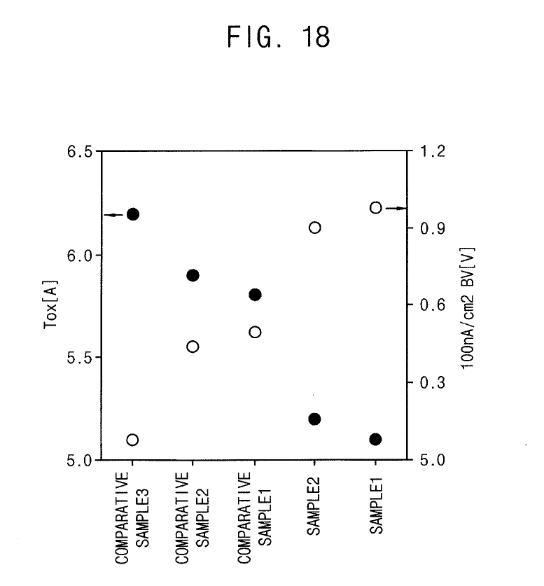

FIG. 18 is a graph illustrating electrical characteristic of storage capacitors based on equivalent oxide thicknesses and breakdown voltages of dielectric layers. The y-axis on the left side of the graph plots the equivalent oxide thickness, and the y-axis on the right hand side plots the breakdown voltages. The equivalent thickness and the breakdown voltages for Samples and Comparative Samples are indicated by filled circles and open circles, respectively.

### Sample 1

The capacitor of Sample 1 has a lower electrode and an upper electrode formed using ruthenium oxides by a CVD processes, respectively. The ruthenium oxides have a rutile crystalline structure. The dielectric layer of the capacitor is formed using titanium oxide doped with aluminum. The dielectric layer is formed using the lower electrode as a seed layer and as result, the dielectric layer has a rutile crystalline structure.

### Sample 2

The capacitor of Sample 2 has a lower electrode of a capacitor formed using ruthenium oxide by a CVD process. The ruthenium oxide deposited by the CVD process had a rutile crystalline structure. The dielectric layer of the capacitor is formed using titanium oxide doped with aluminum. The dielectric layer had a rutile crystalline structure formed using the lower electrode as a seed layer. Unlike the Sample 1, the upper electrode is formed using ruthenium formed by an ALD process.

### Comparative Sample 1

The capacitor of Comparative Sample 1 has a lower electrode formed using ruthenium by an ALD process. The ALD process is controlled so that the ruthenium of the lower electrode has an anatase crystalline structure. The dielectric layer according to Comparative Sample 1 is formed using titanium oxide doped with aluminum. The upper electrode is formed using ruthenium oxide by a CVD process.

### Comparative Sample 2

The storage capacitor of Comparative Sample has a lower electrode and an upper electrode of ruthenium formed by an ALD process. The ruthenium formed by the ALD process had an anatase crystalline structure. The dielectric layer according to Comparative Sample 2 is formed using titanium oxide doped with aluminum. The dielectric layer has amorphous or an anatase crystalline structure.

### Comparative Sample 3

The storage capacitor of Comparative Sample 3 has a lower electrode formed using ruthenium by an ALD process. The ruthenium formed by the ALD process has an anatase crystalline structure. The dielectric layer is formed using titanium oxide doped with aluminum. The upper electrode is formed using ruthenium by a PVD process. The dielectric layer has an amorphous or an anatase crystalline structure.

Referring to FIG. 18, equivalent oxide layers of Example 1 and Example 2 are thinner than those of Comparative Examples 1 to 3. That is, dielectric constants of the dielectric layers according to Examples 1 and 2 were higher than those of the dielectric layers according to Comparative Examples 1 to 3. Thus, even though the capacitors included substantially the same dielectric layers, the dielectric constants of the dielectric layers were changed in accordance with the materials of the electrodes and the processes of forming the electrodes. The dielectric constants of the dielectric layers were dominantly changed in accordance with the materials of the lower electrodes and the processes of forming the lower electrodes. As for the capacitors according to Examples 1 and 2, the lower electrodes were formed using ruthenium oxides by the CVD processes, so that the dielectric layers had relatively high dielectric constants, respectively.

As illustrated in FIG. 18, the capacitors according to Examples 1 and 2 had higher breakdown voltages than those of the capacitors according to Comparative Examples 1 to 3. That is, the capacitors according to Examples 1 and 2 had relatively good leakage current characteristics.

FIG. 19 is a block diagram illustrating a memory system in accordance with example embodiments.

Referring to FIG. 19, the memory system may include a memory device 510 and a memory controller 520 electrically connected to each other. The memory device 510 may include a semiconductor device having a construction substantially the same as or substantially similar to that of one of the semiconductor devices according to example embodiments. The memory controller 520 may provide the memory device 510 with input signals for controlling the operation of the memory device 510.

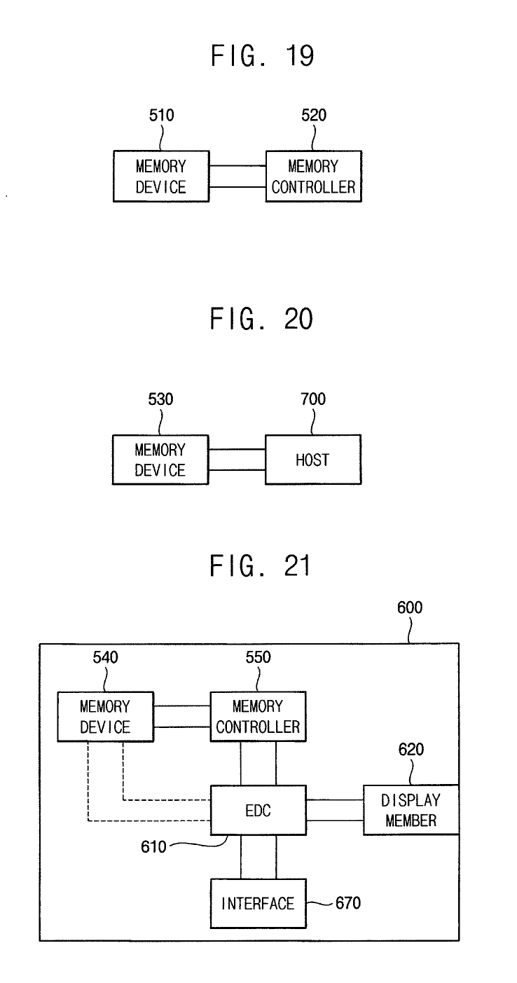

FIG. 20 is a block diagram illustrating a memory system in accordance with example embodiments.

Referring to FIG. 20, the memory system may include a memory device 530 connected to a host system 700. The memory device 530 may include a semiconductor device having a construction substantially the same as or substantially similar to that of one of the semiconductor devices according to example embodiments. The host system 700 may include electronic devices such as a personal computer, a camera, a mobile device, a game console and a communication device. The host system 700 may provide the memory device 530 with input signals for controlling the operation of the memory device 530. The memory device 510 may be used as a data storage media.

FIG. 21 is a block diagram illustrating a memory system in accordance with example embodiments.

Referring to FIG. 21, the memory system may include a portable device 600. The portable device 600 may include an MP3 player, a video player, or a portable multi-media player. As illustrated in FIG. 21, the portable device 600 may include a memory device 540 and a memory controller 550. The memory device 540 may include a semiconductor device having a construction substantially the same as or substantially similar to that of one of the semiconductor devices according to example embodiments.

The portable device 600 also may include an incoder/decoder 610, a display member 620 and an interface 670. The incoder/decoder 610 may input and/or output data (audio, video, etc.) from the memory device 540 through the memory controller 550.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims.

1. A capacitor in a semiconductor memory device, comprising:
a lower electrode formed on a substrate, the lower electrode being formed of a conductive metal oxide having a rutile crystalline structure;
a titanium oxide dielectric layer formed on the lower electrode, the titanium oxide dielectric layer having a rutile crystalline structure and including impurities for reducing a leakage current; and
an upper electrode on the titanium oxide dielectric layer.

2. The capacitor of claim 1, wherein the lower electrode includes ruthenium oxide.

3. The capacitor of claim 1, wherein the lower electrode has one of a circular pillar shape, an elliptical pillar shape, or a polygonal pillar shape.

4. The capacitor of claim 1, wherein the lower electrode has a thickness in a range of about 30 Å to about 500 Å.

5. The capacitor of claim 1, wherein the impurities in the titanium oxide dielectric layer include at least one selected from the group consisting of aluminum (Al), silicon (Si), hafnium (Hf), and zirconium (Zr).

6. The capacitor of claim 1, wherein a concentration of the impurities is in a range of about 0.1 to about 20.0 percent by atomic weight.

7. The capacitor of claim 1, wherein the titanium oxide dielectric layer has a thickness in a range of about 30 to about 150 Å.

8. The capacitor of claim 1, wherein the upper electrode includes a conductive metal oxide having a rutile crystalline structure.

9. The capacitor of claim 8, wherein the conductive metal oxide is ruthenium oxide.

10-21. (canceled)

22. A semiconductor memory device comprising:
a transistor in a supporting structure;
a bit line structure configured to electrically connect to a first impurity region of the transistor;
a pad configured to electrically connect to a second impurity region of the transistor; and
a capacitor which includes:
a lower electrode configured to electrically connect to the pad, the lower electrode including a conductive metal oxide having a rutile crystalline structure;
a titanium oxide dielectric layer on the lower electrode, the titanium oxide dielectric layer including impurities for reducing a leakage current; and
an upper electrode on the titanium oxide dielectric layer.

23. The semiconductor memory device of claim 22, wherein the lower electrode includes ruthenium oxide.

24. The semiconductor memory device of claim 22, wherein the lower electrode has a thickness in a range of about 30 Å to about 500 Å.

25-27. (canceled)

28. A semiconductor memory device comprising:
a supporting structure having a transistor, a bit line, and a pad wherein the bit line is configured to electrically connect to a first impurity region of the transistor and the pad is configured to electrically connect to a second impurity region of the transistor; and
a capacitor which includes:
a lower electrode configured to directly contact the pad, the lower electrode including a conductive metal oxide having a rutile crystalline structure;
a titanium oxide dielectric layer formed on the lower electrode, the titanium oxide dielectric layer having a rutile crystalline structure and including impurities for reducing a leakage current; and
an upper electrode formed on the titanium oxide dielectric layer.

29. The semiconductor memory device of claim 28, wherein the lower electrode includes ruthenium oxide.

30. The semiconductor memory device of claim 29, wherein the lower electrode has a thickness in a range of about 30 Å to about 500 Å and is used as a seed layer for forming the titanium oxide dielectric layer.
